(19) United States
(12) Patent Application Publication
(10) Pub. No.: US 2026/0150538 A1
(43) Pub. Date: May 28, 2026

(54) DISPLAY DEVICE

(71) Applicant: Sharp Display Technology Corporation, Kameyama City (JP)

(72) Inventors: Masahiro IMAI, Kameyama City (JP); Yasuyoshi KAISE, Kameyama City (JP); Fumikazu SHIMOSHIKIRYOH, Kameyama City (JP)

(21) Appl. No.: 19/396,781

(22) Filed: Nov. 21, 2025

(30) Foreign Application Priority Data
Nov. 28, 2024 (JP) 2024-207069

(51) Int. Cl. H10K 59/131; H10K 59/35

(52) U.S. Cl. CPC H10K 59/131; H10K 59/353

(57) ABSTRACT

A display device includes a first display element layer including a plurality of pixels, the plurality of pixels composed of a plurality of primary color pixels, and a second display element layer arranged over the first display element layer, in which the second display element layer includes a plurality of pixel electrodes arranged to overlap with a display region of the first display element layer, and a plurality of lead-out wiring lines each connected to a corresponding one of the plurality of pixel electrodes, and the plurality of lead-out wiring lines arranged with all of the plurality of primary color pixels present in a gap between two adjacent lead-out wiring lines.

### CROSS-REFERENCE TO RELATED APPLICATIONS

This application claims the benefit of priority to Japanese Patent Application Number 2024-207069 filed on Nov. 28, 2024. The entire contents of the above-identified application are hereby incorporated by reference.

### BACKGROUND

### Technical Field

The disclosure relates to a display device including two display element layers.

A display device in which two display panels are overlapped is known. For example, WO 2016/117325 discloses a display device including a first display panel in which pixels are formed in regions defined by a first stripe pattern, and a second display panel in which pixels are formed in regions defined by a second stripe pattern. The first display panel and the second display panel are arranged in an overlapped manner, and the first stripe pattern is inclined at a predetermined angle with respect to the second stripe pattern, thereby reducing the occurrence of moire.

### SUMMARY

When the two display panels are overlapped, in addition to moire, interference between the two display panels may occur, resulting in a reduction in display quality. For example, in the display device described in JP 2023-112406 A, color unevenness and/or luminance unevenness may be observed. For reference, the entire contents of the disclosure of JP 2023-112406 A are incorporated in the present specification by reference.

An object of the disclosure is to suppress the occurrence of color unevenness and/or luminance unevenness in a display device in which two display panels are overlapped.

According to embodiments of the disclosure, solutions described in the following items are provided.

### Item 1

A display device includes a first display element layer including a plurality of pixels, the plurality of pixels composed of a plurality of primary color pixels, and a second display element layer arranged over the first display element layer, in which the second display element layer includes a plurality of pixel electrodes arranged to overlap with a display region of the first display element layer and a plurality of lead-out wiring lines each connected to a corresponding one of the plurality of pixel electrodes, and the plurality of lead-out wiring lines arranged with all of the plurality of primary color pixels present in a gap between two adjacent lead-out wiring lines.

### Item 2

The display device according to item 1, in which the plurality of primary color pixels include a red pixel, a green pixel, and a blue pixel, the plurality of pixels including a column including only the red pixel and the blue pixel and a column including only the green pixel in a longitudinal direction of a display region, and including a column including only the red pixel and the green pixel and a column including only the blue pixel and the green pixel in a 45-degree direction, and the plurality of lead-out wiring lines arranged with the gap between the two adjacent lead-out wiring lines forming an angle of greater than 0 degrees and less than 45 degrees with respect to the longitudinal direction of the display region.

### Item 3

The display device according to item 2, in which the plurality of lead-out wiring lines are configured with the gap between the two adjacent lead-out wiring lines including a portion having an inclination of not less than 5 degrees and not more than 40 degrees with respect to the longitudinal direction of the display region.

### Item 4

The display device according to item 2 or 3, in which a ratio of the red pixel, the green pixel, and the blue pixel present in the gap between the two adjacent lead-out wiring lines is equal in any of the gap between the two adjacent lead-out wiring lines.

### Item 5

The display device according to item 2 or 3, in which a ratio of the red pixel, the green pixel, and the blue pixel present in the gap between the two adjacent lead-out wiring lines is equal to a ratio of an area of the red pixel, an area of the green pixel, and an area of the blue pixel in an entire display region.

### Item 6

A display device includes a first display element layer including a plurality of pixels, and a second display element layer arranged over the first display element layer, in which the second display element layer includes a plurality of pixel electrodes arranged to overlap with a display region of the first display element layer, a plurality of lead-out wiring lines each connected to a corresponding one of the plurality of pixel electrodes, and a plurality of additional wiring lines each arranged to overlap with any gap between two adjacent lead-out wiring lines among the plurality of lead-out wiring lines.

### Item 7

The display device according to item 6, further includes a first display element layer including a plurality of pixels, and a second display element layer arranged over the first display element layer, in which the second display element layer further includes a plurality of pixel electrodes arranged to overlap with a display region of the first display element layer, a plurality of lead-out wiring lines each connected to a corresponding one of the plurality of pixel electrodes, and auxiliary wiring lines each including a portion overlapping with any gap between two adjacent lead-out wiring lines among the plurality of lead-out wiring lines and a portion overlapping with a gap between pixel electrodes adjacent to each other among the plurality of pixel electrodes, and the auxiliary wiring lines being connected to any one of the adjacent pixel electrodes.

According to the embodiments of the disclosure, the occurrence of color unevenness and/or luminance unevenness in a display device in which two display panels are overlapped is suppressed.

### BRIEF DESCRIPTION OF DRAWINGS

The disclosure will be described with reference to the accompanying drawings, wherein like numbers reference like elements.

FIG. 1A is a schematic exploded perspective view of a display device 100 according to an embodiment of the disclosure, illustrating an off state.

FIG. 1B is a schematic exploded perspective view of the display device 100 according to the embodiment of the disclosure, illustrating an on state.

FIG. 2A is a plan view illustrating an arrangement of pixel electrodes 21 and lead-out wiring lines 23P that form a liquid crystal element layer 20P.

FIG. 2B is a cross-sectional view of the liquid crystal element layer 20P taken along line 2B-2B′ in FIG. 2A.

FIG. 3 is a plan view illustrating an arrangement relationship between an organic EL element layer 10 and the lead-out wiring lines 23P when the liquid crystal element layer 20P illustrated in FIG. 2A is arranged on the organic EL element layer 10.

FIG. 4 is a plan view illustrating an arrangement relationship between the organic EL element layer 10 and lead-out wiring lines 23A when a liquid crystal element layer 20A is arranged on the organic EL element layer 10 in the display device 100 according to the embodiment of the disclosure.

FIG. 5 is a schematic plan view illustrating lead-out wiring lines 23B extending in a longitudinal direction while being bent in a V-shape.

FIG. 6 is a schematic diagram illustrating a state in which the lead-out wiring lines 23B extending in the longitudinal direction while being bent in the V-shape are arranged on an organic EL element layer 10a including pixels in a stripe arrangement.

FIG. 7 is a diagram illustrating an arrangement relationship between an organic EL element layer 10 and lead-out wiring lines 23C in a display device according to another embodiment of the disclosure.

FIG. 8 is a diagram illustrating an arrangement relationship between an organic EL element layer 10 and lead-out wiring lines 23D in a display device according to still another embodiment of the disclosure.

FIG. 9 is a schematic diagram for explaining a design concept of an arrangement relationship between pixels of the organic EL element layer 10 and wiring lines of a liquid crystal element layer.

FIG. 10 is a schematic diagram for explaining a design concept of an arrangement relationship between the pixels of the organic EL element layer 10 and the wiring lines of the liquid crystal element layer.

FIG. 11 is a schematic diagram for explaining a design concept of an arrangement relationship between the pixels of the organic EL element layer 10 and wiring lines.

FIG. 12 is a diagram illustrating an arrangement relationship between pixels of an organic EL element layer 10 and lead-out wiring lines 23E in a display device according to still another embodiment of the disclosure.

FIG. 13A is a schematic plan view illustrating an arrangement relationship between pixel electrodes 21 and lead-out wiring lines 23F in a display device according to still another embodiment of the disclosure.

FIG. 13B is a schematic plan view illustrating an arrangement relationship between the pixel electrodes 21 and additional wiring lines 25F.

FIG. 13C is a schematic cross-sectional view of a liquid crystal element layer 20E taken along line 13C-13C′ in FIG. 13A and FIG. 13B.

FIG. 14A is a schematic plan view illustrating an arrangement relationship between the pixel electrodes 21 and the lead-out wiring lines 23F in the display device according to still another embodiment of the disclosure.

FIG. 14B is a schematic plan view illustrating an arrangement relationship between the pixel electrodes 21 and auxiliary wiring lines 27G.

FIG. 14C is a schematic cross-sectional view of a liquid crystal element layer 20G taken along line 13C-13C′ in FIG. 14A and FIG. 14B.

### DESCRIPTION OF EMBODIMENTS

Hereinafter, display devices according to embodiments of the disclosure will be described with reference to the accompanying drawings. The display devices according to the embodiments of the disclosure are not limited to those exemplified below.

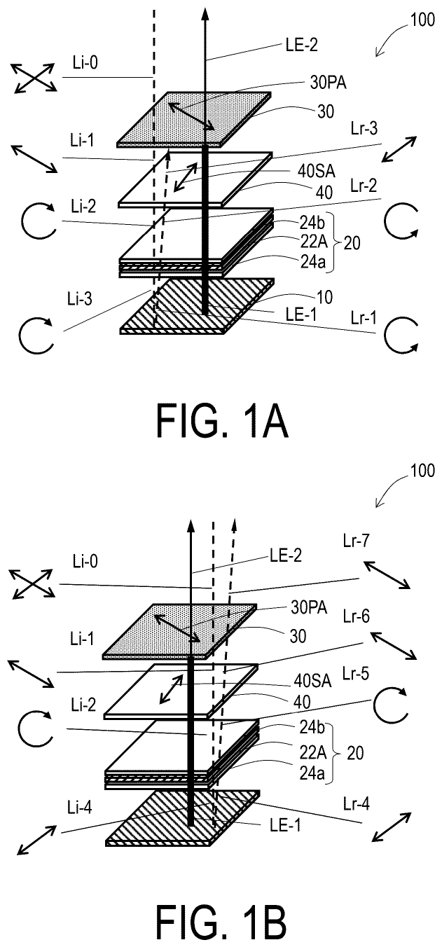

The display device according to the embodiment of the disclosure includes a first display element layer and a second display element layer arranged on an observer side of the first display element layer. For example, JP 2023-112406 A discloses a display device 100 illustrated in FIG. 1. As described below, a display device 100 according to the embodiment of the disclosure satisfies a specific relationship between an arrangement of wiring lines in a liquid crystal element layer 20 and an arrangement of pixels in an organic EL element layer 10.

The display device 100 includes the organic EL element layer 10 and the liquid crystal element layer 20 arranged on the organic EL element layer 10, the liquid crystal element layer 20 including two transparent substrates 24a and 24b, and a liquid crystal layer 22A arranged between the two transparent substrates 24a and 24b, the liquid crystal element layer 20 being configured such that retardation of approximately a quarter wavelength is generated in light passing through the liquid crystal layer 22A by applying a voltage to the liquid crystal layer 22A, and a polarizer 30 arranged on an observer side of the liquid crystal element layer 20. The display device 100 further includes a retarder 40 arranged between the liquid crystal element layer 20 and the polarizer 30, but the retarder 40 may be omitted depending on a display mode.

Note that “retardation” as used herein refers to retardation for light having a wavelength around 550 nm, which has high visibility in visible light. The retardation of approximately a quarter wavelength refers to a retardation of 138 nm±20 nm, for example, but this may vary depending on required display quality. Although a VA mode is preferable as the liquid crystal layer 22A from the viewpoint of a contrast ratio, various modes such as a transverse electrical field mode and a TN mode may be used.

Here, the liquid crystal element layer 20 and the polarizer 30 are configured to perform reflective display using light reflected within the organic EL element layer 10, and to perform self-luminous display using light emitted from the organic EL element layer 10. The liquid crystal element layer 20 does not include a reflective layer and does not function as a reflective liquid crystal display element even when combined with the polarizer 30. In addition, the display device 100 does not include a polarizer between the liquid crystal element layer 20 and the organic EL element layer 10, so the liquid crystal element layer 20 cannot form a transmissive liquid crystal display element.

For example, a display device described in JP 6700079 B is a display device in which a reflective liquid crystal element layer and an organic EL element layer are layered with an adhesive layer/insulating film/adhesive layer interposed therebetween. In this display device, the reflective liquid crystal element layer includes a reflective electrode and an opening, and is configured such that light emitted from the organic EL element layer passes through the opening of the reflective liquid crystal element layer. The reflective liquid crystal element layer and the organic EL element layer included in this display device can each perform display independently. However, pixels of the organic EL element layer need to be arranged in correspondence with pixels of the liquid crystal element layer, and high alignment accuracy is required. In addition, the liquid crystal element layer generally has a black matrix (a light blocking portion that partitions the pixels) and a color filter layer, which reduce light utilization efficiency.

In contrast, the display device 100 includes only the polarizer 30 arranged on the observer side of the liquid crystal element layer 20, and does not include a polarizer between the liquid crystal element layer 20 and the organic EL element layer 10. As a result, the light utilization efficiency in self-luminous display by the organic EL element layer 10 is improved. In addition, in the reflective display, the light utilization efficiency is improved because the loss of light at the rear surface portion described above is eliminated. In addition, the liquid crystal element layer 20 preferably does not include the black matrix, and preferably does not include a color filter layer. When the black matrix is not included, the degree of freedom in alignment increases, and the light utilization efficiency can be improved. In addition, by not including the color filter layer, the degree of freedom in alignment increases, and light utilization efficiency can be improved.

Further, from the viewpoint of transmittance, the liquid crystal element layer 20 preferably does not include an element such as a thin film transistor (TFT) in a display region (active area) in which a plurality of pixels are arranged in a matrix shape, and is preferably driven by segment driving, for example. Pixel electrodes and wiring lines are preferably formed of a transparent conductive layer. In the case of performing TFT driving, the TFT and a drive circuit are preferably provided outside the display region. In addition, a memory circuit may be further provided outside the display region. Examples of materials for the transparent conductive layer include, for example, indium tin oxide (ITO) and indium zinc oxide (IZO).

Referring to FIG. 1A, an operation state of the display device 100 in an off state (herein, a state in which no voltage is applied to the liquid crystal layer 22A and no retardation is given to light passing through the liquid crystal layer 22A) will be described.

Unpolarized external light Li-0 becomes linearly polarized light Li-1 parallel to a polarization transmission axis 30PA after passing through the polarizer 30, and then becomes, for example, right handed circularly-polarized light Li-2 after passing through the retarder 40. Even when the right handed circularly-polarized light Li-2 passes through the liquid crystal element layer 20 in the off state, the polarization state is maintained, and the right handed circularly-polarized light Li-2 enters the organic EL element layer 10 while remaining as right handed circularly-polarized light Li-3. The right handed circularly-polarized light Li-3 is reflected by the organic EL element layer 10 and becomes left handed circularly-polarized light Lr-1. Even when the left handed circularly-polarized light Lr-1 passes through the liquid crystal element layer 20, the polarization state is maintained, and the left handed circularly-polarized light Lr-1 enters the retarder 40 while remaining as left handed circularly-polarized light Lr-2. The left handed circularly-polarized light Lr-2 becomes linearly polarized light Lr-3 after passing through the retarder 40. A polarization direction of the linearly polarized light Lr-3 is orthogonal to that of linearly polarized light Li-1, and is also orthogonal to the polarization transmission axis 30PA of the polarizer 30, so linearly polarized light Lr-3 is absorbed by the polarizer 30. That is, the display device 100 in the off state displays black in the reflective display.

On the other hand, in the on state of the display device 100 illustrated in FIG. 1B (a state in which a voltage is applied to the liquid crystal layer 22A and retardation of approximately a quarter wavelength is generated for light passing through the liquid crystal layer 22A), right handed circularly-polarized light Li-2 becomes linearly polarized light Li-4 after passing through the liquid crystal element layer 20 in the on state. A polarization direction of the linearly polarized light Li-4 is a direction orthogonal to the linearly polarized light Li-1. The linearly polarized light Li-4 enters the organic EL element layer 10, is reflected by the organic EL element layer 10, and becomes linearly polarized light Lr-4. A polarization direction of the linearly polarized light Lr-4 is the same as that of the linearly polarized light Li-4. The linearly polarized light Lr-4 passes through the liquid crystal element layer 20 in the on state, becomes right handed circularly-polarized light Lr-5, and enters the retarder 40. The right handed circularly-polarized light Lr-5 entered the retarder 40 passes through the retarder 40 and becomes linearly polarized light Lr-6. A polarization direction of the linearly polarized light Lr-6 is the same as that of the linearly polarized light Li-1, and the linearly polarized light Lr-6 passes through the polarizer 30.

Here, for example, when the transmittance of the polarizer 30 is 42%, the transmittance of the retarder 40 is 100%, the transmittance of the liquid crystal element layer 20 is 85%, and the reflectivity of the organic EL element layer 10 is 90%, reflected light Lr-7 exiting from the polarizer 30 is about 27% of the external light Li-0. The reflective display using the reflected light Lr-7 becomes a mirror display when specular reflection occurs at the organic EL element layer 10. By providing a scattering layer (not illustrated) between the organic EL element layer 10 and the liquid crystal element layer 20, the reflective display can be changed to a white display. Note that depending on a degree of scattering, the reflective display can also be changed to an intermediate display between the mirror display and the white display (i.e., a silver-colored display). When, as the scattering layer, a scattering layer having polarization dependence and having an azimuthal direction in which scattering is strong that forms an angle within plus-minus 5 degrees with respect to the polarization transmission axis 30PA of the polarizer 30 is used, the contrast ratio can be increased as compared with a case in which a general scattering layer that isotropically scatters light is used.

As the scattering layer, a phase separation type scattering layer (for example, a phase separation AG film manufactured by Daicel Corporation) that has no uneven structure on a surface can be suitably used. Further, as the scattering layer having polarization dependence, for example, a polarized light scattering film (JP 5468766 B) manufactured by DuPont Teijin Films can be suitably used.

Light LE-1 emitted from the organic EL element layer 10 is unpolarized light and is partially absorbed by the polarizer 30 regardless of whether the liquid crystal element layer 20 is in the on state or the off state. For example, when the transmittance of the polarizer 30 is set to 42%, light LE-2 used for self-luminous display is 42% of the light LE-1.

Note that the organic EL element layer 10 can be switched on/off in each of the on state and the off state in the above description.

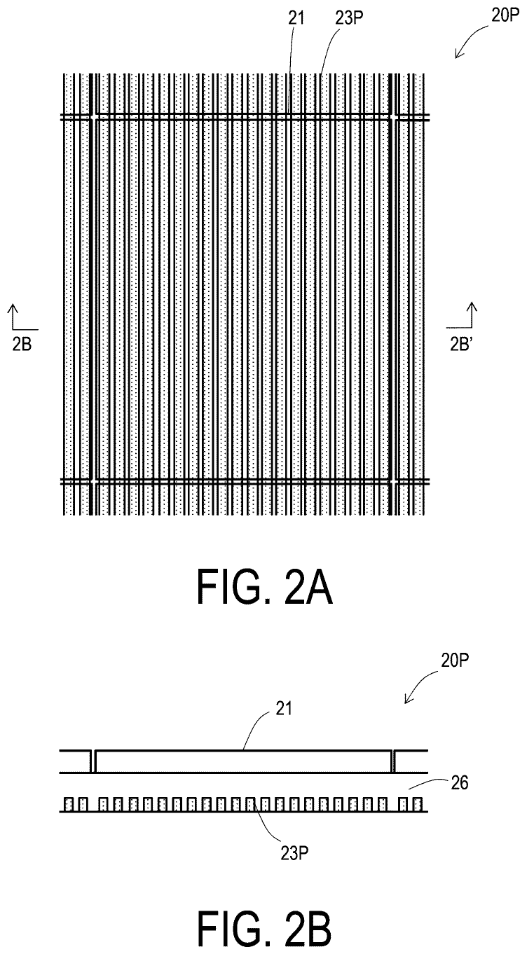

The arrangement of pixel electrodes 21 and the lead-out wiring lines 23P that form a liquid crystal element layer 20P will be described with reference to FIGS. 2A and 2B. The liquid crystal element layer 20P indicates a liquid crystal element layer 20P of a comparative example including a general structure in which a plurality of lead-out wiring lines 23P extending in the vertical (longitudinal) direction are arranged in the horizontal (lateral) direction, which is used as the liquid crystal element layer 20 of the display device 100 illustrated in FIG. 1.

The pixel electrodes 21 and the lead-out wiring lines 23P are provided on a side of the liquid crystal layer 22A of the transparent substrate 24a, and common electrodes (not illustrated) are provided on a side of the liquid crystal layer 22A of the transparent substrate 24b. The common electrodes are provided so as to face all of a plurality of pixel electrodes 21 with the liquid crystal layer 22A interposed therebetween. FIG. 2A is a plan view illustrating the arrangement of the pixel electrodes 21 and the lead-out wiring lines 23P that form the liquid crystal element layer 20P, and FIG. 2B is a cross-sectional view of the liquid crystal element layer 20P taken along line 2B-2B′ in FIG. 2A.

The plurality of lead-out wiring lines 23P are arranged in a lower layer of the plurality of pixel electrodes 21 arranged in a matrix shape with an insulating layer 26 interposed therebetween. The pixel electrodes 21 and the corresponding lead-out wiring lines 23P are connected to each other in contact holes (not illustrated) formed in the insulating layer 26. The plurality of lead-out wiring lines 23P are connected to a drive circuit (not illustrated) outside the display region. The insulating layer 26 may be formed using, for example, a photosensitive organic insulating resin. The plurality of lead-out wiring lines 23P are uniformly arranged in a plane so that the transmittance is uniform in the plane. The interval between the adjacent lead-out wiring lines 23P is narrower than the width of each lead-out wiring line 23P.

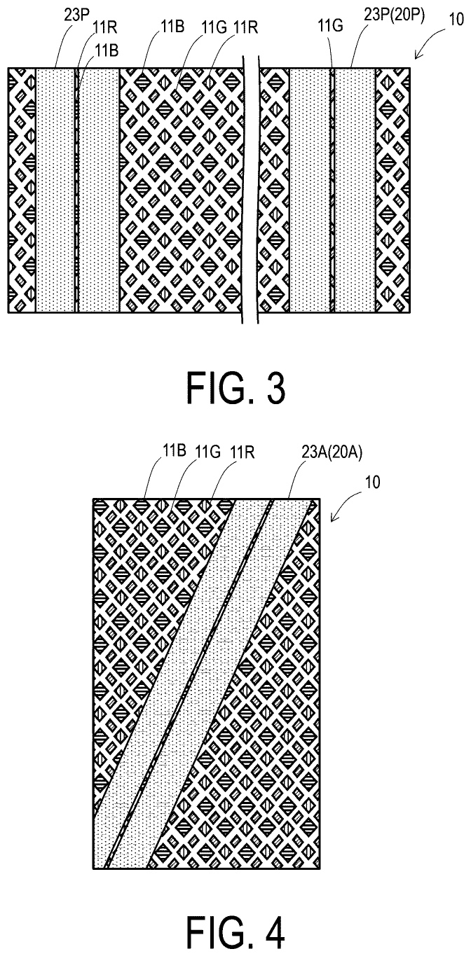

FIG. 3 is a plan view illustrating an arrangement relationship between the organic EL element layer 10 and the lead-out wiring lines 23P when the liquid crystal element layer 20P illustrated in FIG. 2A is arranged on the organic EL element layer 10. The organic EL element layer 10 includes three types of pixels (primary color pixels: a red pixel 11R, a green pixel 11G, and a blue pixel 11B) arranged in a PenTile pattern. In FIG. 3, in order to clarify the arrangement of the pixels, two adjacent pairs of the lead-out wiring lines 23P, among the plurality of lead-out wiring lines 23P illustrated in FIG. 2A, are schematically illustrated.

As can be seen from FIG. 3, the distribution of the pixels in the organic EL element layer 10 that is present between two adjacent lead-out wiring lines 23P is different. Between the two adjacent lead-out wiring lines 23P on the left side of FIG. 3, only the red pixels 11R and the blue pixels 11B are present, and between the two adjacent lead-out wiring lines 23P on the right side, only the green pixels 11G are present. The lead-out wiring lines 23P are formed of the transparent conductive layer, and the transmittance of visible light differs depending on the presence or absence of the lead-out wiring lines 23P. As a result, color unevenness and/or luminance unevenness may be visually recognized in the display by the organic EL element layer 10.

FIG. 4 is a plan view illustrating an arrangement relationship between the organic EL element layer 10 and lead-out wiring lines 23A when a liquid crystal element layer 20A is arranged on the organic EL element layer 10 as the liquid crystal element layer 20 in the display device 100 according to the embodiment of the disclosure. The liquid crystal element layer 20A is different from the liquid crystal element layer 20P only in the configuration and arrangement of the lead-out wiring lines 23A. In FIG. 4 as well, in order to clarify the arrangement of the pixels, one pair of lead-out wiring lines 23A that are adjacent to each other among a plurality of lead-out wiring lines 23A is schematically illustrated.

As illustrated in FIG. 4, the lead-out wiring lines 23A included in the liquid crystal element layer 20A are provided so as to be arranged obliquely with respect to the arrangement of the pixels of the organic EL element layer 10, and three types of pixels (primary color pixels: the red pixel 11R, the green pixel 11G, and the blue pixel 11B) are present between two adjacent lead-out wiring lines 23A.

As exemplified here, when the red pixel 11R and the blue pixel 11B are arranged in the longitudinal direction, as well as the red pixel 11R and the green pixel 11G, and the blue pixel 11B and the green pixel 11G, are arranged in a 45-degree direction, inclination of a gap between the two adjacent lead-out wiring lines 23A (inclination with respect to the longitudinal direction) is set to be greater than 0 degrees and less than 45 degrees. That is, the gap between the two adjacent lead-out wiring lines 23A is inclined so as to avoid the directions (0 degrees and 45 degrees) which do not include pixels of all colors. For example, when the inclination accuracy is 5 degrees, the inclination of the gap of the lead-out wiring lines 23A is designed to be in a range of not less than 5 degrees and not more than 40 degrees. For example, as illustrated in FIG. 4, the gap between the lead-out wiring lines 23A may be inclined so that the red pixel 11R in a certain column overlaps with the blue pixel 11B one row below in an adjacent column.

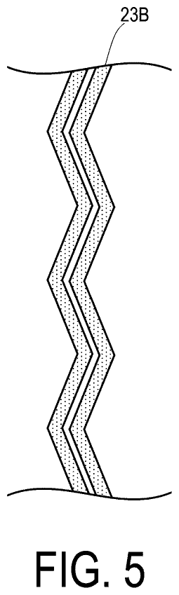

At this time, as schematically illustrated in FIG. 5, lead-out wiring lines 23B extending in the longitudinal direction while being bent in a V-shape may be provided. Each of the straight line portions of the lead-out wiring lines 23B is provided so as to satisfy the above conditions.

By providing a scattering layer (not illustrated) between the organic EL element layer 10 and the liquid crystal element layer 20, color unevenness and/or luminance unevenness can be made more difficult to be visually recognized. Note that, as described above, white display can be achieved by providing the scattering layer between the organic EL element layer 10 and the liquid crystal element layer 20, but when the known liquid crystal element layer 20P is used, the hue between the lead-out wiring lines 23B may appear to vary.

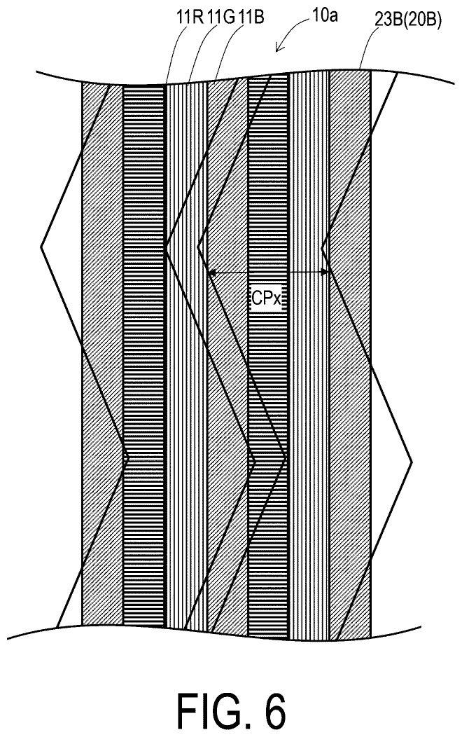

FIG. 6 is a schematic diagram illustrating a state in which a liquid crystal element layer 20B including the lead-out wiring lines 23B extending in the longitudinal direction while being bent in a V-shape is disposed on an organic EL element layer 10a including pixels in a stripe arrangement. As illustrated in FIG. 6, when the three types of pixels (primary color pixels: the red pixel 11R, the green pixel 11G, and the blue pixel 11B) of the organic EL element layer 10a are in the stripe arrangement, the lead-out wiring lines 23B extending in the longitudinal direction while being bent in a V-shape as illustrated in FIG. 5 may be provided. In this case, it is preferable that the widths of the lead-out wiring lines 23B in a lateral direction be substantially the same as the arrangement pitches CPx of the three types of pixels (color display pixels) CP in the lateral direction as exemplified. Note that the widths of the lead-out wiring lines 23B in the lateral direction may be substantially integral multiples of the pitch CPx, the multiples being not less than substantially two times. In this manner, the distribution of the three primary colors can be made uniform. Note that, in FIG. 6, for the sake of simplicity, each pixel column including a plurality of pixels is illustrated as one continuous longitudinally long region.

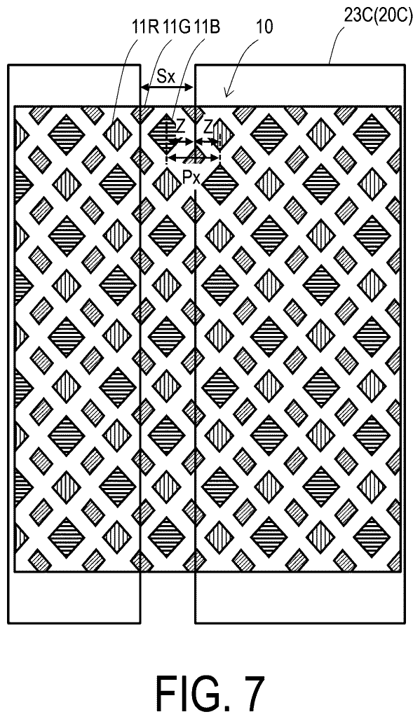

Next, an arrangement relationship between an organic EL element layer 10 and lead-out wiring lines 23C of a liquid crystal element layer 20C in a display device according to another embodiment of the disclosure will be described with reference to FIG. 7.

As illustrated in FIG. 7, a pitch Px in a lateral direction of pixels corresponds, for example, to the distance from the vertex of a red pixel 11R in a certain row to the position of the same vertex of the red pixel 11R in the next row. Here, since the PenTile arrangement is exemplified, the width Z of the minimum unit in which a ratio of R pixels, G pixels, and B pixels is constant corresponds to ½ of the pitch Px of the pixels in the lateral direction. In the display device illustrated in FIG. 7, an example is illustrated in which an interval (lateral direction) Sx between the two adjacent lead-out wiring lines 23C is substantially two times the width Z of the minimum unit in which the ratio of the R pixels, the G pixels, and the B pixels is constant (that is, substantially equal to Px), but the interval (lateral direction) Sx between the two adjacent lead-out wiring lines 23C is preferably substantially the same as the width Z of the minimum unit in which the ratio of the R pixels, the G pixels, and the B pixels is constant, or substantially integral multiples not less than 2.

By setting the interval (lateral direction) Sx between the two adjacent lead-out wiring lines 23C to be substantially integral multiples of the width Z of the minimum unit in which the ratio of the R pixels, the G pixels, and the B pixels is constant, the area of the three types of primary color pixels present in the region where the organic EL element layer 10 and the lead-out wiring lines 23C overlap each other and the area of the three types of primary color pixels present in the region where the organic EL element layer 10 and the interval between the two adjacent lead-out wiring lines 23C overlap each other can be made substantially equal to each other, and thus, the occurrence of color unevenness and/or luminance unevenness can be suppressed.

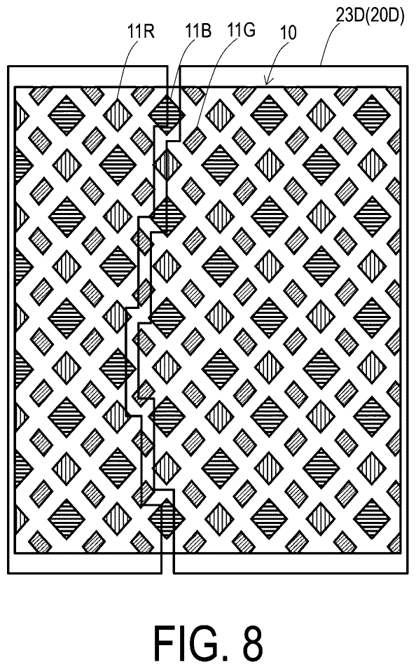

Next, an arrangement relationship between an organic EL element layer 10 and lead-out wiring lines 23D included in a liquid crystal element layer 20D in a display device according to still another embodiment of the disclosure will be described with reference to FIG. 8.

In the display device illustrated in FIG. 8, the position of the interval between the two adjacent lead-out wiring lines 23D changes stepwise along the longitudinal direction. In this example, the areas of three types of primary color pixels present in a region where the organic EL element layer 10 and the lead-out wiring lines 23D overlap each other can be substantially equal to the areas of the three types of primary color pixels present in a region where the organic EL element layer 10 and an interval between the two adjacent lead-out wiring lines 23D overlap each other, and therefore, the occurrence of color unevenness and/or luminance unevenness can be suppressed.

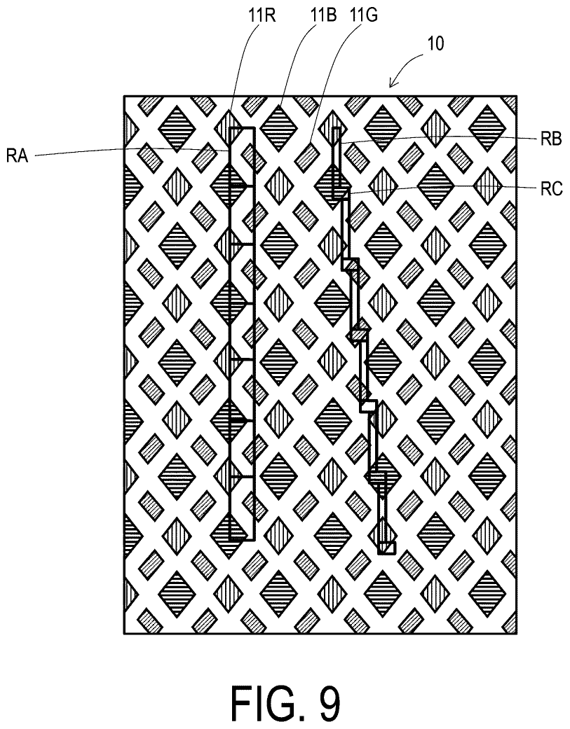

Next, reference is made to FIG. 9. FIG. 9 is a schematic diagram for explaining a design concept of an arrangement relationship between the pixels and wiring lines of the organic EL element layer 10, which can suppress the occurrence of color unevenness and/or luminance unevenness.

The ratio of the areas of the three types of primary color pixels included in a region RA illustrated in FIG. 9 is the same as the ratio of the areas of the three types of primary color pixels in the entire display region of the organic EL element layer 10. The lateral width of the region RA is one half of the pitch Px of the pixels in the lateral direction, and the length of the region RA in the longitudinal direction is equal to a pitch Py of the pixels in the longitudinal direction. A region having the lateral width that is 1/M (M is a positive integer) of the width of the region RA is referred to as a region RB. In the example illustrated in FIG. 9, M=3. In addition, a region having the longitudinal width that is 1/N (N is a positive integer) of the width of the region RA is referred to as a region RC. In the example illustrated in FIG. 9, N=5.

As illustrated in FIG. 9, the ratio of the areas of the three types of primary color pixels included in the region obtained by combining the M×N sets of the region RB and the region RC is the same as the ratio of the areas of the three types of primary color pixels in the entire display region of the organic EL element layer 10 (x represents multiplication). Therefore, by providing two adjacent lead-out wiring lines 23 such that the interval between the adjacent lead-out wiring lines 23 is represented by a region obtained by combining M×N sets of the region RB and the region RC as illustrated in FIG. 9, the occurrence of color unevenness and/or luminance unevenness can be suppressed.

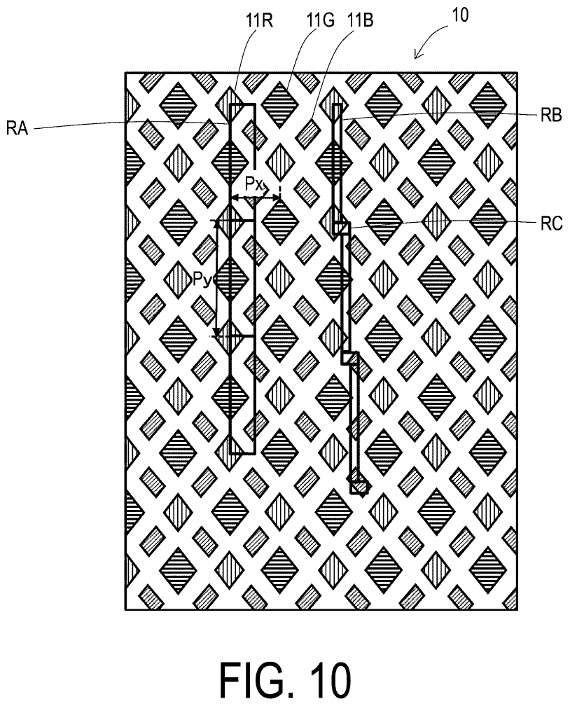

Further, as illustrated in FIG. 10, even when the lead-out wiring lines 23 are provided in such a manner that an interval between the two adjacent lead-out wiring lines 23 is represented by combining M×N sets of the region RB, which is referred to as a region having a lateral width of ⅓ (M=3) of the lateral width of the region RA, and the region RC, which is referred to as a region having a lateral width of ⅔ (M=3) of the lateral width of the region RA and a longitudinal width of 1/10 (N=10) of the longitudinal width of the region RA, the occurrence of color unevenness and/or luminance unevenness can be suppressed.

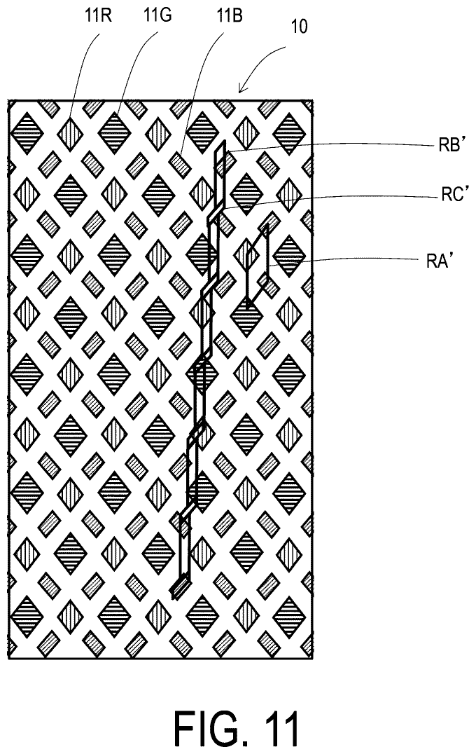

In the examples illustrated in FIGS. 9 and 10, the region RA, in which the ratio of the areas of the three types of primary color pixels is the same as the ratio of the areas of the three types of primary color pixels in an entire display region of the organic EL element layer 10, has a rectangular shape ((Px/2)×Py), but is not limited thereto. For example, the region RA may be a parallelogram, as in a region RA′ illustrated in FIG. 11. In the region RA′, the ratio of the areas of the three types of primary color pixels included in the region RA′ is the same as the ratio of the areas of the three types of primary color pixels in the entire display region of the organic EL element layer 10, as in the region RA illustrated in FIG. 9. A region having a lateral width of 1/M (M is a positive integer, M=3) of the lateral width of the region RA′ is a region RB′, and a region having a longitudinal width of 1/N (N is a positive integer, N=5) of the longitudinal width of the region RA′ is a region RC′, and both the region RB′ and the region RC′ are also parallelograms.

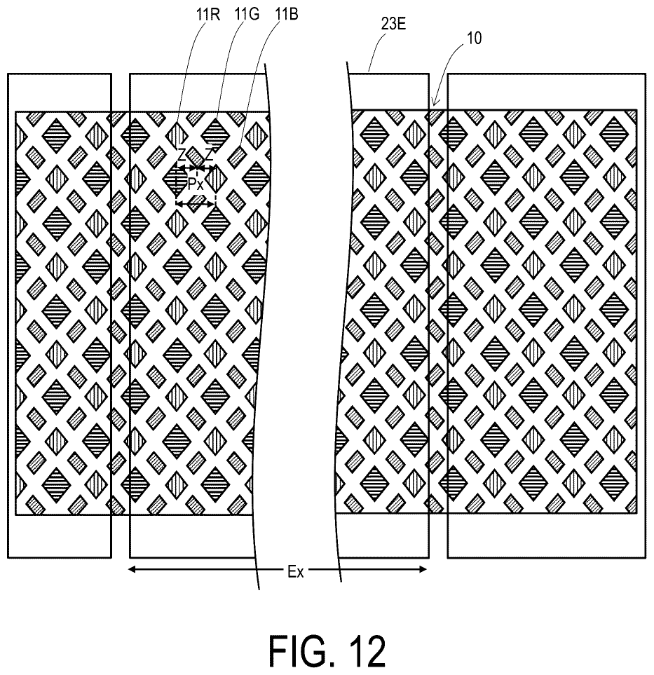

Further, as illustrated in FIG. 12, the occurrence of color unevenness and/or luminance unevenness can be suppressed also by setting the widths (lateral direction) Ex of lead-out wiring lines 23E to be substantially integral multiples of the width Z of the minimum unit in which the ratio of the R pixels, the G pixels, and the B pixels is constant. The ratio of the areas of the three types of primary color pixels included in each gap between the two adjacent lead-out wiring lines 23E is not the same as the ratio of the areas of the three types of primary color pixels in the entire display region of the organic EL element layer 10, but the ratio of the areas of the three types of primary color pixels included in each gap is constant, and thus color unevenness and/or luminance unevenness are less likely to be visually recognized. Of course, by making the ratio of the areas of the three types of primary color pixels included in each gap between the two adjacent lead-out wiring lines 23E the same as the ratio of the areas of the three types of primary color pixels in an entire display region of the organic EL element layer 10, color unevenness and/or luminance unevenness can be made even more difficult to be visually recognized.

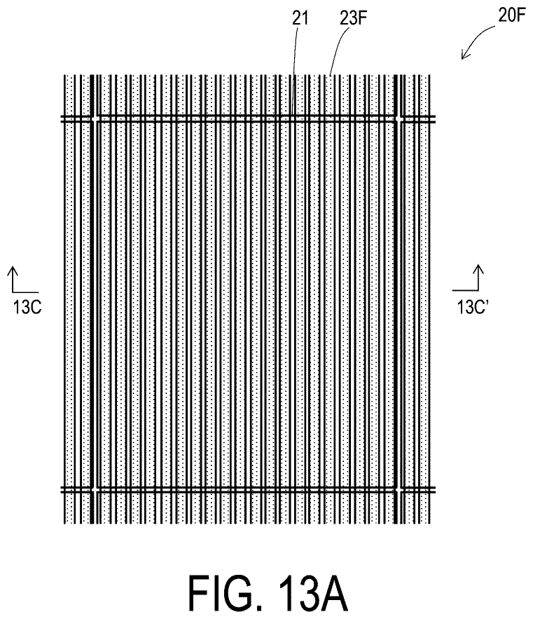

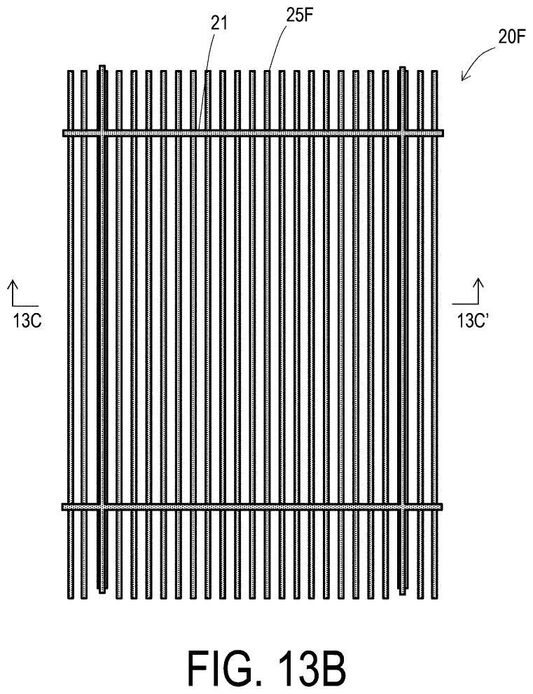

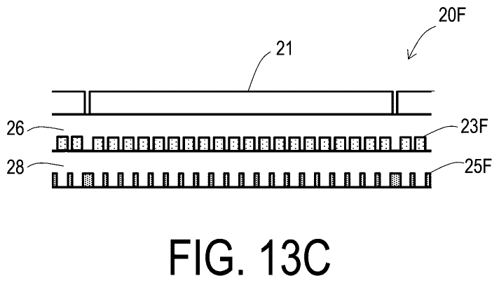

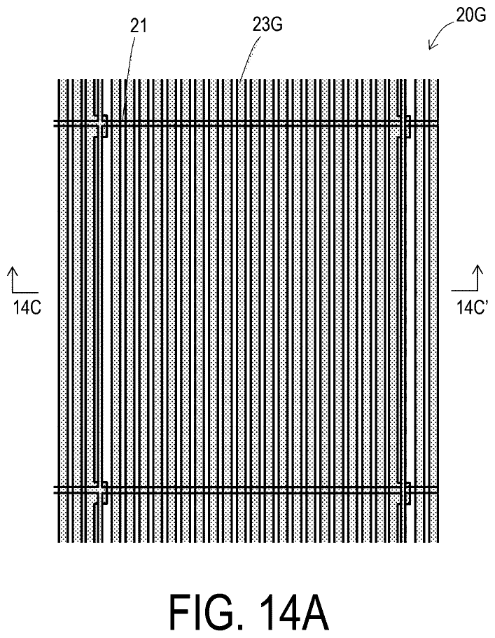

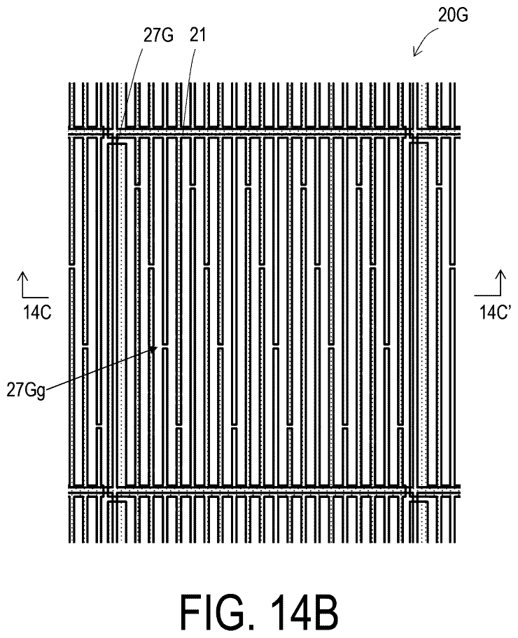

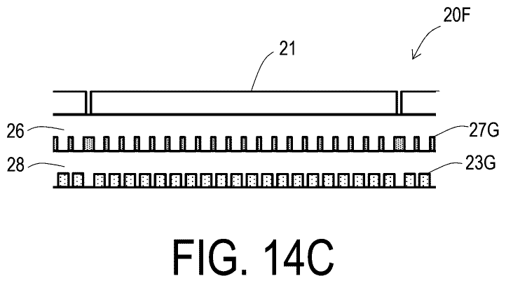

Next, a display device according to still another embodiment of the disclosure will be described with reference to FIGS. 13A to 13C and FIGS. 14A to 14C.

FIGS. 13A, 13B, and 13C illustrate a liquid crystal element layer 20F of the display device according to the embodiment. The liquid crystal element layer 20F of the display device according to the present embodiment includes pixel electrodes 21, lead-out wiring lines 23F, and additional wiring lines 25. FIG. 13A is a schematic plan view illustrating an arrangement relationship between the pixel electrodes 21 and the lead-out wiring lines 23F, FIG. 13B is a schematic plan view illustrating an arrangement relationship between the pixel electrodes 21 and additional wiring lines 25F, and FIG. 13C is a schematic cross-sectional view of the liquid crystal element layer 20F taken along line 13C-13C′ in FIG. 13A and FIG. 13B.

The lead-out wiring lines 23F are provided in a lower layer of the pixel electrodes 21 with an insulating layer 26 interposed therebetween, and the additional wiring lines 25F are provided in a lower layer of the lead-out wiring lines 23F with an insulating layer 28 interposed therebetween. The additional wiring lines 25F are arranged so as to overlap with a gap between the two adjacent lead-out wiring lines 23F. The additional wiring lines 25F are also formed of a transparent conductive layer, similarly to the lead-out wiring lines 23F. The insulating layer 28 may be formed by using, for example, a photosensitive organic insulating resin, similarly to the insulating layer 26. By providing the additional wiring lines 25F, the occurrence of color unevenness and/or luminance unevenness is suppressed.

Here, the lead-out wiring lines 23F electrically connected to the pixel electrodes 21 are arranged in an upper layer (on a side closer to the pixel electrodes 21), and the additional wiring lines 25F that do not need to be electrically connected to the pixel electrodes 21 are arranged in a lower layer (on a side farther from the pixel electrodes 21). The additional wiring lines 25F are preferably formed of the same transparent conductive material as the lead-out wiring lines 23F from the viewpoint of optical characteristics and mass productivity, but electrical conductivity is not required.

In addition, the lead-out wiring lines 23F arranged in the lower layer of the pixel electrodes 21 are provided at equal pitches, but in the gap portions between the adjacent pixel electrodes 21, the gaps between the lead-out wiring lines 23F are wider than those in other portions, and the widths of the additional wiring lines 25F provided corresponding thereto are also wider than those in other portions. The luminance unevenness may be visually recognized at discontinuous portions of these pitches. As a countermeasure, the lead-out wiring lines 23F and the additional wiring lines 25F may be arranged at equal pitches also in the gap portions between the adjacent pixel electrodes 21.

Next, reference is made to FIG. 14A, FIG. 14B and FIG. 14C.

FIGS. 14A, 14B, and 14C illustrate a liquid crystal element layer 20G of the display device according to the embodiment. The liquid crystal element layer 20G of the display device according to the present embodiment includes auxiliary wiring lines 27G in addition to the pixel electrodes 21 and lead-out wiring lines 23G. FIG. 14A is a schematic plan view illustrating an arrangement relationship between the pixel electrodes 21 and the lead-out wiring lines 23G, FIG. 14B is a schematic plan view illustrating an arrangement relationship between the pixel electrodes 21 and the auxiliary wiring lines 27G, and FIG. 14C is a schematic cross-sectional view of the liquid crystal element layer 20G taken along line 14C-14C′ in FIG. 14A and FIG. 14B.

As illustrated in FIG. 14C, a cross-sectional structure of the liquid crystal element layer 20G is such that the auxiliary wiring lines 27G are provided in a lower layer of the pixel electrodes 21 with the insulating layer 26 interposed therebetween, and the lead-out wiring lines 23G are provided in a lower layer of the auxiliary wiring lines 27G with the insulating layer 28 interposed therebetween. The pixel electrodes 21 are connected to the corresponding lead-out wiring lines 23G in contact holes (not illustrated) formed in the insulating layer 26 and the insulating layer 28.

A gap is present between the adjacent pixel electrodes 21, and a desired voltage is not applied to a portion of the liquid crystal layer present in a region corresponding to the gap, so that the alignment state of the liquid crystal molecules is different from that in the pixel region. This difference in the alignment state may be visually recognized as a lattice pattern display unevenness.

Therefore, as illustrated in FIG. 14C, the auxiliary wiring lines 27G are provided under the pixel electrodes 21 so as to overlap with gap portions, and by making the potential of the auxiliary wiring lines 27G are set to the same potential as that of the adjacent pixel electrodes 21, the gap portions can be suppressed from being visually recognized as the display unevenness in a lattice pattern. The auxiliary wiring lines 27G are arranged in an upper layer (on a side closer to the pixel electrodes 21) and the lead-out wiring lines 23G are arranged in a lower layer (on a side farther from the pixel electrodes 21) so that the electrical field generated by the auxiliary wiring lines 27G easily reaches the liquid crystal layer. Such a structure is disclosed, for example, in JP 2024-024523 A. For reference, the entire contents of the disclosure of JP 2024-024523 A are incorporated in the present specification by reference. In the display device according to the present embodiment, by further providing the auxiliary wiring lines 27G including a portion overlapping with the gaps between the two adjacent lead-out wiring lines 23G, the occurrence of the luminance unevenness due to the lead-out wiring lines 23G can be suppressed. The auxiliary wiring lines 27G may be referred to as auxiliary electrodes 27G. The auxiliary wiring lines 27G are also formed of the transparent conductive layer similarly to the lead-out wiring lines 23G, and are preferably formed of the same transparent conductive material as the lead-out wiring lines 23G from the viewpoint of optical characteristics and mass productivity.

The auxiliary wiring lines 27G also have an L-shaped portion so as to overlap with a gap between the pixel electrodes 21, and the L-shaped portion of the auxiliary wiring lines 27G is arranged so as to overlap with (straddle) the peripheral portions of the four pixel electrodes 21 located at the upper right, lower right, upper left, and lower left. Each of the auxiliary wiring lines 27G is connected to one of the four adjacent pixel electrodes 21. Here, the auxiliary wiring lines 27G are connected in a contact hole (not illustrated) so as to have the same potential as the upper right pixel electrode 21. Accordingly, the auxiliary wiring lines 27G need to be electrically separated for each pixel, and are electrically separated for each pixel by gaps 27Gg. At this time, as illustrated in FIG. 14B, the gaps 27Gg separating the auxiliary wiring lines 27G for each pixel are arranged discretely so as not to be concentrated linearly, whereby the occurrence of luminance unevenness can be suppressed.

In the above description, the organic EL element layer is exemplified as the first display element layer, and the liquid crystal element layer arranged on the observer side of the first display element layer is exemplified as the second display element layer, but the display device according to the embodiment of the disclosure is not limited thereto. As the first display element layer, for example, a liquid crystal element layer can be used.

### INDUSTRIAL APPLICABILITY

According to the embodiment of the disclosure, the occurrence of color unevenness and/or luminance unevenness in the display device in which two display panels are overlapped can be suppressed.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. A display device, comprising:
a first display element layer including a plurality of pixels, the plurality of pixels composed of a plurality of primary color pixels; and
a second display element layer arranged over the first display element layer,
wherein the second display element layer includes a plurality of pixel electrodes arranged to overlap with a display region of the first display element layer and a plurality of lead-out wiring lines each connected to a corresponding one of the plurality of pixel electrodes, and the plurality of lead-out wiring lines arranged with all of the plurality of primary color pixels present in a gap between two adjacent lead-out wiring lines.

2. The display device according to claim 1,
wherein the plurality of primary color pixels include a red pixel, a green pixel, and a blue pixel, the plurality of pixels including a column including only the red pixel and the blue pixel and a column including only the green pixel in a longitudinal direction of a display region, and including a column including only the red pixel and the green pixel and a column including only the blue pixel and the green pixel in a 45-degree direction, and the plurality of lead-out wiring lines arranged with the gap between the two adjacent lead-out wiring lines forming an angle of greater than 0 degrees and less than 45 degrees with respect to the longitudinal direction of the display region.

3. The display device according to claim 2,
wherein the plurality of lead-out wiring lines are configured with the gap between the two adjacent lead-out wiring lines including a portion having an inclination of not less than 5 degrees and not more than 40 degrees with respect to the longitudinal direction of the display region.

4. The display device according to claim 2,
wherein a ratio of the red pixel, the green pixel, and the blue pixel present in the gap between the two adjacent lead-out wiring lines is equal in any of the gaps between the two adjacent lead-out wiring lines.

5. The display device according to claim 2,
wherein a ratio of the red pixel, the green pixel, and the blue pixel present in the gap between the two adjacent lead-out wiring lines is equal to a ratio of an area of the red pixel, an area of the green pixel, and an area of the blue pixel in an entire display region.

6. A display device, comprising:
a first display element layer including a plurality of pixels; and
a second display element layer arranged over the first display element layer,
wherein the second display element layer includes a plurality of pixel electrodes arranged to overlap with a display region of the first display element layer, a plurality of lead-out wiring lines each connected to a corresponding one of the plurality of pixel electrodes, and a plurality of additional wiring lines each arranged to overlap with any gap between two adjacent lead-out wiring lines among the plurality of lead-out wiring lines.

7. The display device according to claim 6, comprising:
a first display element layer including a plurality of pixels; and
a second display element layer arranged over the first display element layer,
wherein the second display element layer further includes a plurality of pixel electrodes arranged to overlap with a display region of the first display element layer, a plurality of lead-out wiring lines each connected to a corresponding one of the plurality of pixel electrodes, and auxiliary wiring lines each including a portion overlapping with any gap between two adjacent lead-out wiring lines among the plurality of lead-out wiring lines and a portion overlapping with a gap between pixel electrodes adjacent to each other among the plurality of pixel electrodes, and the auxiliary wiring lines being connected to any one of the adjacent pixel electrodes.
